(19) United States
(12) Patent Application Publication
(10) Pub. No.: US 2026/0123472 A1
(43) Pub. Date: Apr. 30, 2026

(54) Semiconductor Devices and Methods of Making Bridge Modules and Chiplet Structures Having the Bridge Modules

(71) Applicant: STATS ChipPAC Management Pte. Ltd., Singapore (SG)

(72) Inventors: TaeWoo Lee, Incheon (KR); HeeSoo Lee, Incheon (KR); EunHee Myung, Gyeonggi-do (KR)

(73) Assignee: STATS ChipPAC Management Pte. Ltd., Singapore (SG)

(21) Appl. No.: 18/930,596

(22) Filed: Oct. 29, 2024

(51) Int. Cl. H01L 23/538; H01L 21/48; H01L 21/683; H01L 23/00; H01L 25/065; H01L 25/16

(52) U.S. Cl. CPC H10W 70/614; H10W 70/05; H10W 70/611; H10W 90/00; H10W 90/401; H10P 72/74; H10P 72/7424; H10W 72/072; H10W 72/241; H10W 90/724

(57) ABSTRACT

A semiconductor device has a bridge die comprising a contact pad. An electrical component is mounted to the bridge die to form a bridge module. The bridge module is disposed over a carrier. A first conductive layer is formed on the carrier. A first insulating layer is formed over the first conductive layer and bridge module. An opening is formed through the first insulating layer to expose the first conductive layer. A second conductive layer is formed over the first insulating layer. The carrier is removed. A first semiconductor die is electrically coupled to the electrical component and bridge die.

### FIELD OF THE INVENTION

The present invention relates in general to semiconductor devices and, more particularly, to semiconductor devices and methods of making a bridge module, and chiplet structures having the bridge module.

### BACKGROUND OF THE INVENTION

Semiconductor devices are commonly found in modern electronic products. Semiconductor devices perform a wide range of functions such as signal processing, high-speed calculations, transmitting and receiving electromagnetic signals, controlling electronic devices, transforming sunlight to electricity, and creating visual images for television displays. Semiconductor devices are found in the fields of communications, power conversion, networks, computers, entertainment, and consumer products. Semiconductor devices are also found in military applications, aviation, automotive, industrial controllers, and office equipment.

Semiconductor device manufacturers are continually striving to make smaller semiconductor devices to meet the demands of electronic device manufacturers and consumers alike. At the same time, more and more complex semiconductor devices are demanded by device manufacturers. Bridge die can be embedded within semiconductor substrates to provide a tighter pitch of interconnect and higher total bandwidth than the substrate itself can provide. However, continually shrinking end devices requires even more advanced integration. Therefore, a need exists for improved semiconductor devices and methods of making bridge modules and chiplet structures having the bridge modules.

### BRIEF DESCRIPTION OF THE DRAWINGS

FIGS. 1a-1j illustrate forming a bridge module in a first embodiment;

FIGS. 2a-2o illustrate forming a chiplet with the bridge module of the first embodiment;

FIGS. 3a-3f illustrate forming a bridge module in a second embodiment;

FIGS. 4a-4e illustrate forming a chiplet with the bridge module of the second embodiment;

FIGS. 5a-5d illustrate additional bridge module embodiments;

FIGS. 6a and 6b illustrate another embodiment of forming a chiplet with the bridge modules; and

FIGS. 7a and 7b illustrate an electronic device with the chiplets.

### DETAILED DESCRIPTION OF THE DRAWINGS

The present invention is described in one or more embodiments in the following description with reference to the figures, in which like numerals represent the same or similar elements. While the invention is described in terms of the best mode for achieving the invention's objectives, it will be appreciated by those skilled in the art that it is intended to cover alternatives, modifications, and equivalents as may be included within the spirit and scope of the invention as defined by the appended claims and their equivalents as supported by the following disclosure and drawings. The features shown in the figures are not necessarily drawn to scale. Elements assigned the same reference number in the figures have a similar function and description to each other. The term “semiconductor die” as used herein refers to both the singular and plural form of the words, and accordingly, can refer to both a single semiconductor device and multiple semiconductor devices.

Semiconductor devices are generally manufactured using two complex manufacturing processes: front-end manufacturing and back-end manufacturing. Front-end manufacturing involves the formation of a plurality of die on the surface of a semiconductor wafer. Each die on the wafer contains active and passive electrical components, which are electrically connected to form functional electrical circuits. Active electrical components, such as transistors and diodes, have the ability to control the flow of electrical current. Passive electrical components, such as capacitors, inductors, and resistors, create a relationship between voltage and current necessary to perform electrical circuit functions.

Back-end manufacturing refers to cutting or singulating the finished wafer into the individual semiconductor die and packaging the semiconductor die for structural support, electrical interconnect, and environmental isolation. To singulate the semiconductor die, the wafer is scored and broken along non-functional regions of the wafer called saw streets or scribes. The wafer is singulated using a laser cutting tool or saw blade. After singulation, the individual semiconductor die are disposed on a package substrate that includes pins or contact pads for interconnection with other system components. Contact pads formed over the semiconductor die are then connected to contact pads within the package. The electrical connections can be made with conductive layers, bumps, stud bumps, conductive paste, or wirebonds. An encapsulant or other molding material is deposited over the package to provide physical support and electrical isolation. The finished package is then inserted into an electrical system and the functionality of the semiconductor device is made available to the other system components.

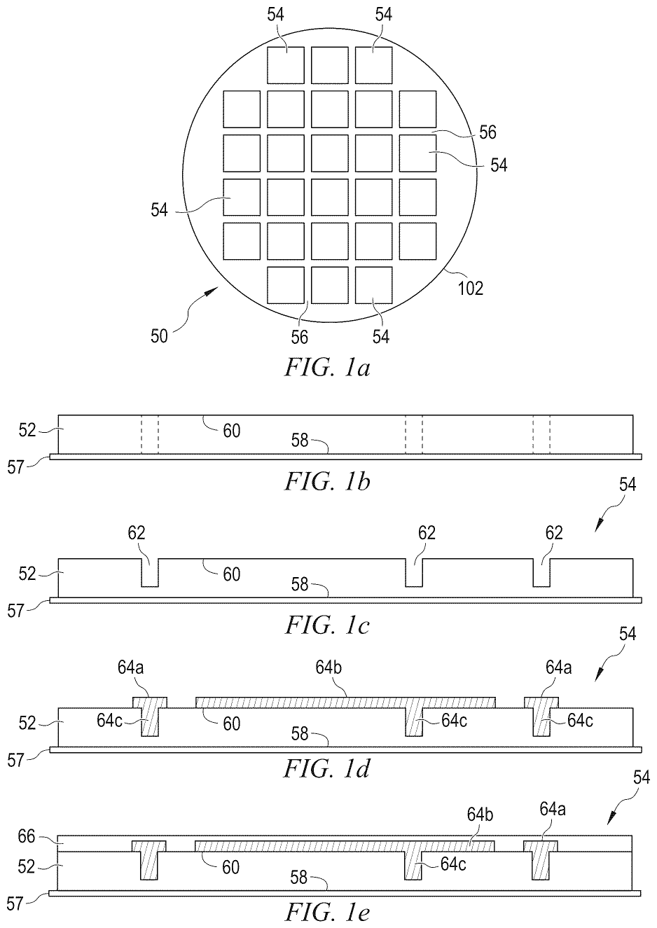

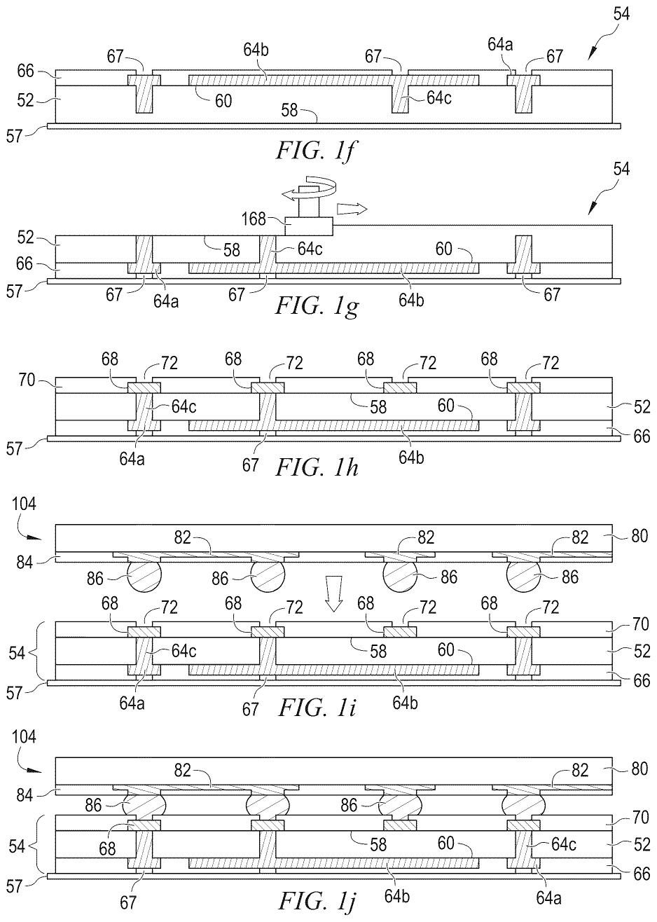

FIGS. 1a-1g illustrate a process of forming a bridge module for inclusion in a chiplet design. FIG. 1a shows a semiconductor wafer 50 with a base substrate material 52, such as silicon, germanium, aluminum phosphide, aluminum arsenide, gallium arsenide, gallium nitride, indium phosphide, silicon carbide, or other bulk material for structural support. Non-silicon substrates are used in other embodiments, e.g., glass, insulating material, or a PCB material. Semiconductor materials are more commonly used due to the maturity of manufacturing processes for forming fine pitched interconnects on silicon.

A plurality of bridge die 54 is formed on wafer 50 separated by a non-active, inter-die wafer area or saw street 56. Saw street 56 provides cutting areas to singulate semiconductor wafer 50 into individual bridge die 54. Wafer 50 begins as a single uniform body of semiconductor material. FIG. 1b shows a cross-sectional view of a portion of semiconductor material 52 at the beginning of the process of forming a bridge die 54. Wafer 50 is placed on a carrier 57 for processing.

In FIG. 1c, a plurality of openings 62 is formed through bridge die 54 at locations where conductive vias are desired for vertical electrical interconnect through the bridge die. Openings 62 are formed by deep reactive-ion etching (DRIE), mechanical drilling, chemical etching, or another suitable means. Openings 62 are formed only partially through bridge die 54. In other embodiments, openings 62 are formed completely through bridge die 54.

A conductive layer 64 is formed over surface 60 of semiconductor wafer 50 in FIG. 1d. Conductive layer 64 is formed using physical vapor deposition (PVD), chemical vapor deposition (CVD), electrolytic plating, electroless plating, sputtering, or other suitable metal deposition process. Conductive layer 64 can be one or more layers of aluminum (Al), copper (Cu), tin (Sn), nickel (Ni), gold (Au), silver (Ag), or other suitable electrically conductive material. Any conductive layer described above or below can be formed using the same methods and materials as conductive layer 64.

Conductive layer 64 is patterned to include contact pads 64a and conductive traces 64b. The conductive material of conductive layer 64 also fills openings 62 to form conductive vias 64c into or through bridge die 54. To operate as a bridge die, bridge die 54 includes contact pads 64a near two opposing edges of each bridge die, each being paired with a contact pad on the opposite edge of the bridge die 54 by a conductive trace 64b. Those contact pads 64a paired across bridge die 54 by a conductive trace 64b will ultimately provide fine-pitched electrical interconnect between two overlying functional semiconductor die in a chiplet, i.e., operate as an interconnect bridge.

When bridge die 54 is incorporated into a semiconductor package, e.g., a chiplet or system-in-package, two other semiconductor die will be disposed over the opposing edges of bridge die 54. Each overlying semiconductor die will be connected to one side of bridge die 54 using contact pads 64a, and then the bridge die will interconnect the two overlying semiconductor die to each other by conductive traces 64b. Other contact pads 64a are optionally formed for electrical interconnect to other components within the bridge module being formed and not necessarily for interconnect between two other die.

In FIG. 1e, a passivation or solder resist layer 66 is formed over conductive layer 64 to protect the conductive layer. Solder resist layer 66 can be formed using any of the methods and materials described below for insulating layers generally. Openings 67 are formed through solder resist layer 66 in FIG. 1f using chemical etching, photolithography, or another suitable means, to expose contact pads 64a.

In FIG. 1g, bridge die 54 is flipped and returned to carrier 57 or another suitable carrier with surface 58 exposed for further processing. A grinder 168, or another suitable means, is used to remove a portion of semiconductor material over conductive vias 64c to expose the conductive vias for subsequent electrical interconnect.

In FIG. 1h, a conductive layer 68 is formed over surface 58 of semiconductor wafer 50. Conductive layer 68 is formed using the methods and materials described above for conductive layer 64. Conductive layer 68 is patterned to include contact pads and, in some embodiments, conductive traces extending between the contact pads. Solder resist layer 70 is formed over conductive layer 68 as described above for solder resist layer 66. Openings 72 are formed through solder resist layer 70 to expose contact pads of conductive layer 68 for subsequent electrical interconnect.

In some embodiments, opposing surfaces 58 and 60 optionally contain analog or digital circuits implemented as active devices, passive devices, conductive layers, and dielectric layers formed on or within the die and electrically interconnected according to the electrical design and function of the die. For example, the circuits may include one or more transistors, diodes, and other circuit elements formed within surfaces 58 or 60 to implement analog circuits or digital circuits, such as a digital signal processor (DSP), application specific integrated circuit (ASIC), memory, or other signal processing circuit. Bridge die 54 may also contain IPDs, such as inductors, capacitors, and resistors, for RF signal processing. In other embodiments, bridge die 54 contain no active or passive components, except for conductive layer 64 being formed over surface 60 and conductive layer 68 being formed over surface 58.

In FIG. 1i, another electrical component 80 is disposed over bridge die 54 and mounted to the bridge die in FIG. 1j. Electrical component 80 is a semiconductor die with active circuits interconnected by conductive layer 82 in one embodiment. In other embodiments, electrical component 80 has passive circuits formed as IPDs within conductive layers formed over the semiconductor die with or without active components formed in the die. Electrical component 80 can be any suitable electrical component or combination of electrical components, including semiconductor die, semiconductor packages, system-in-package (SiP) modules, a chiplet, active or passive discrete components, or any combination thereof. A solder resist or passivation layer 84 is formed over conductive layer 82 as described above for solder resist layers 66 and 70.

Solder bumps 86 or another suitable interconnect structure is formed on contact pads of conductive layer 82. An electrically conductive bump material is deposited over conductive layer 82 in openings of insulating layer 84 using an evaporation, electrolytic plating, electroless plating, ball drop, or screen printing process. The bump material can be Al, Sn, Ni, Au, Ag, lead (Pb), bismuth (Bi), Cu, solder, and combinations thereof, with an optional flux solution. For example, the bump material can be eutectic Sn/Pb, high-lead solder, or lead-free solder. The bump material is bonded to conductive layer 82 using a suitable attachment or bonding process. In one embodiment, the bump material is reflowed by heating the material above its melting point to form balls or bumps 86. In one embodiment, bump 86 is formed over an under-bump metallization (UBM) having a wetting layer, a barrier layer, and an adhesion layer.

A bridge module 104 is completed in FIG. 1j by reflowing bumps 86 to mechanically and electrically couple electrical component 80 to bridge die 54. Bridge die 54, and electrical component 80 if necessary, can be singulated prior to mounting in FIG. 1j using a saw blade or laser cutting tool. In other embodiments, electrical component 80 is an individual component at the die level mounted on wafer 50 prior to singulation of the wafer, or components 80 are mounted as a wafer onto wafer 50 and both wafers are singulated together. Bridge module 104 includes a bridge die 54 to provide interconnect between two overlying semiconductor die, and electrical component 80 to provide supplemental electrical functionality for the overlying semiconductor die. An optional encapsulant or underfill can be deposited between bridge die 54 and electrical component 80.

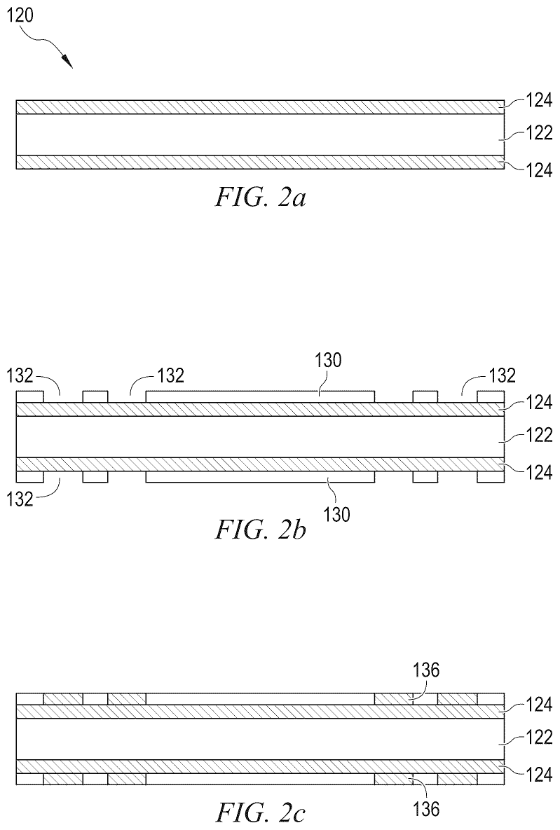

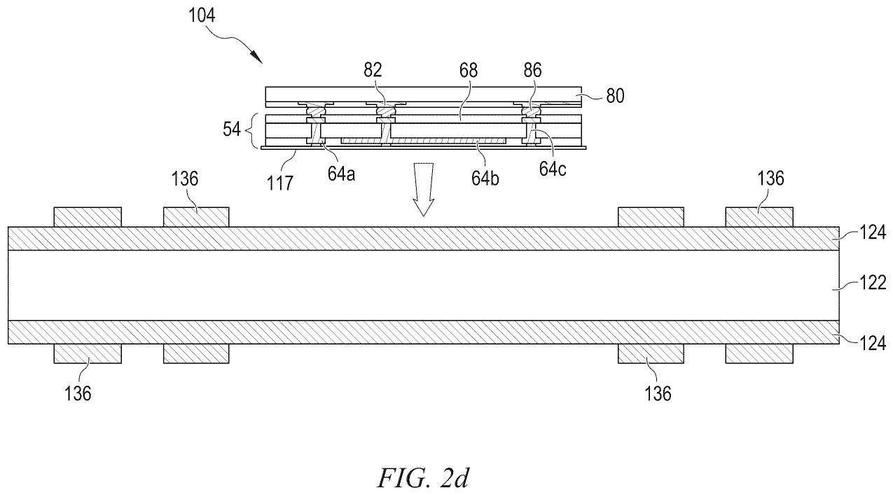

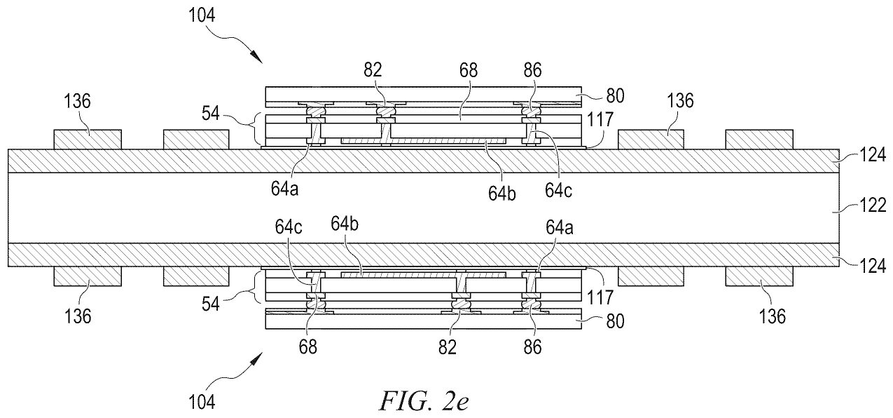

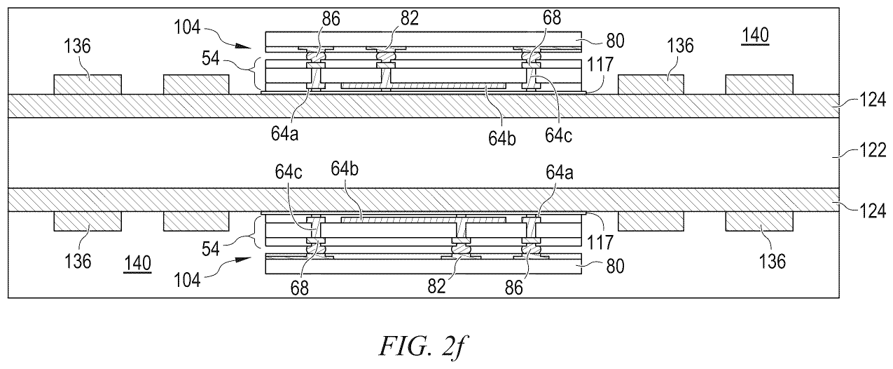

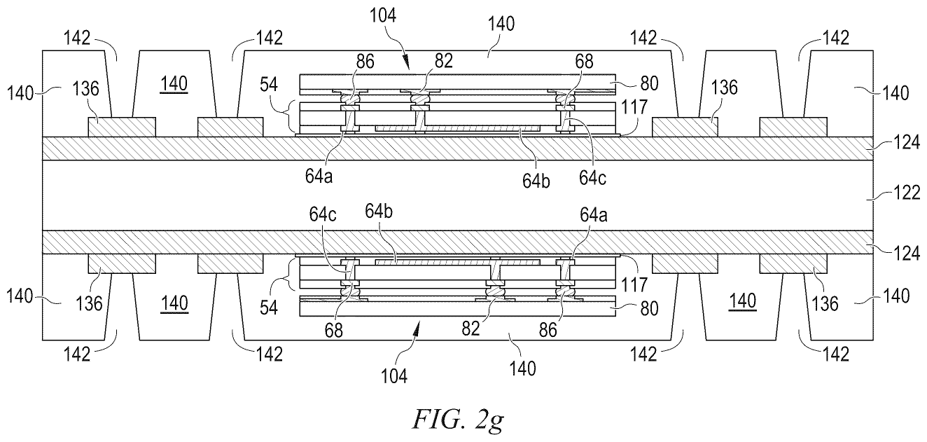

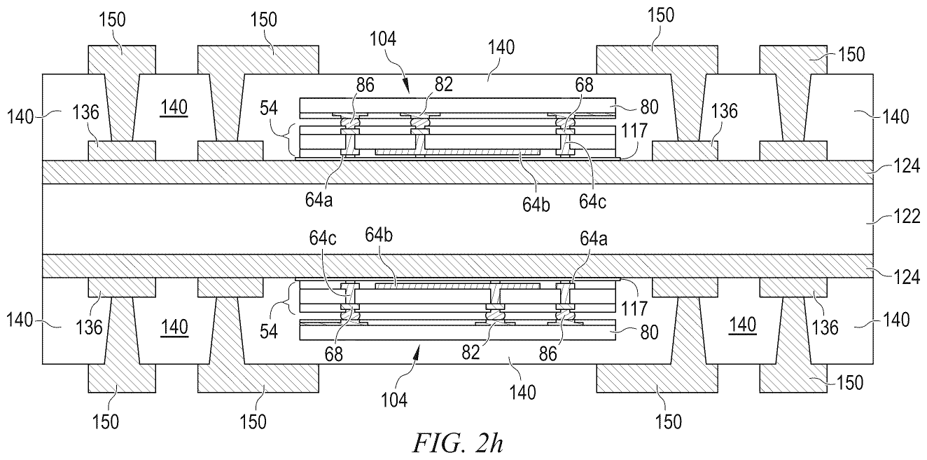

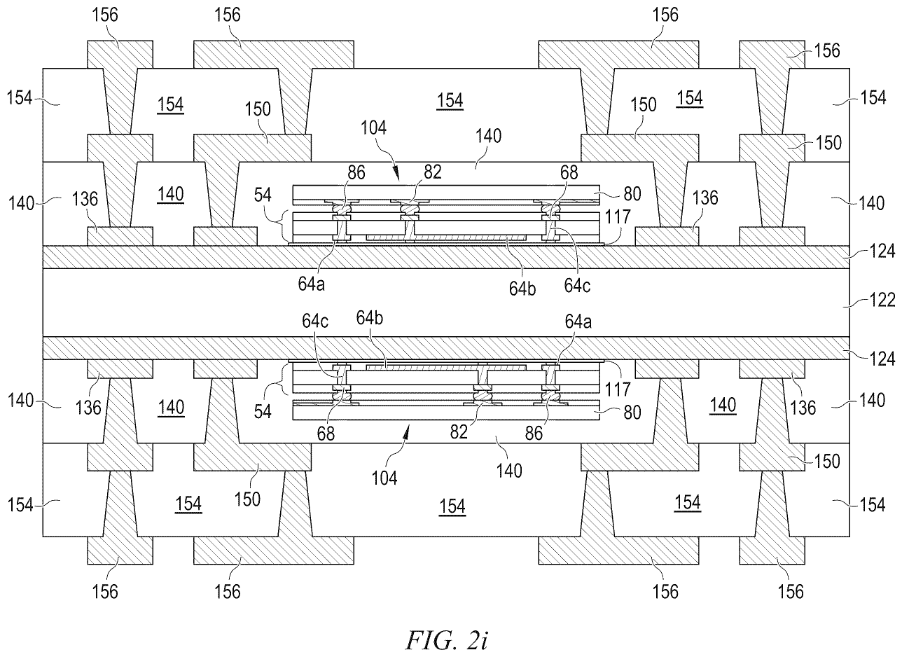

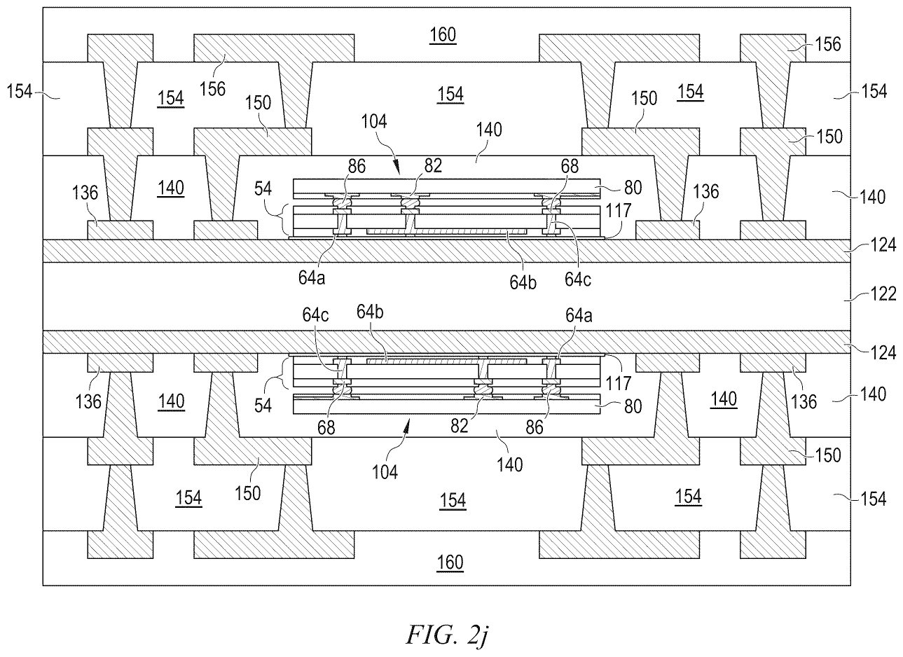

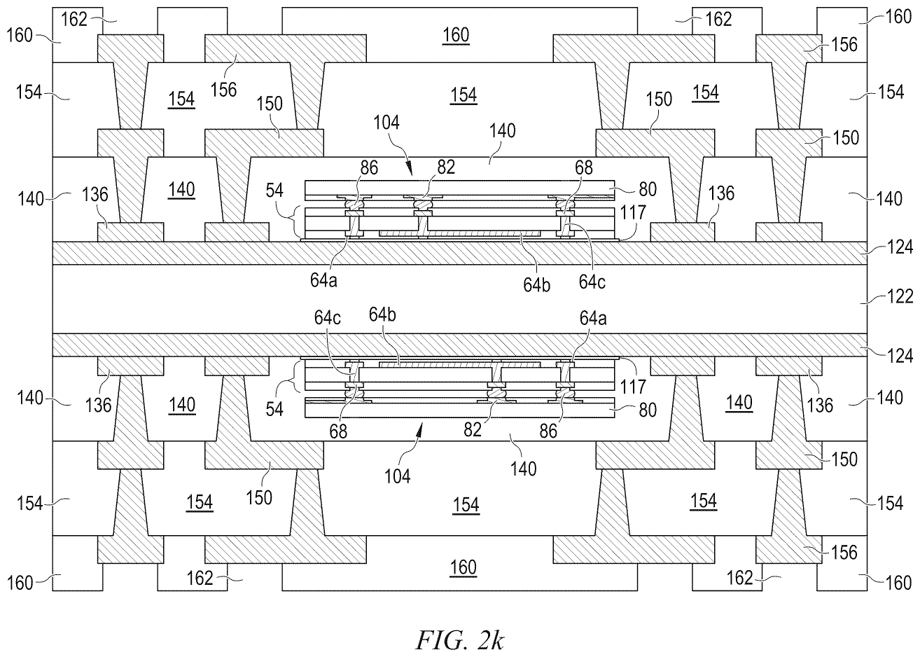

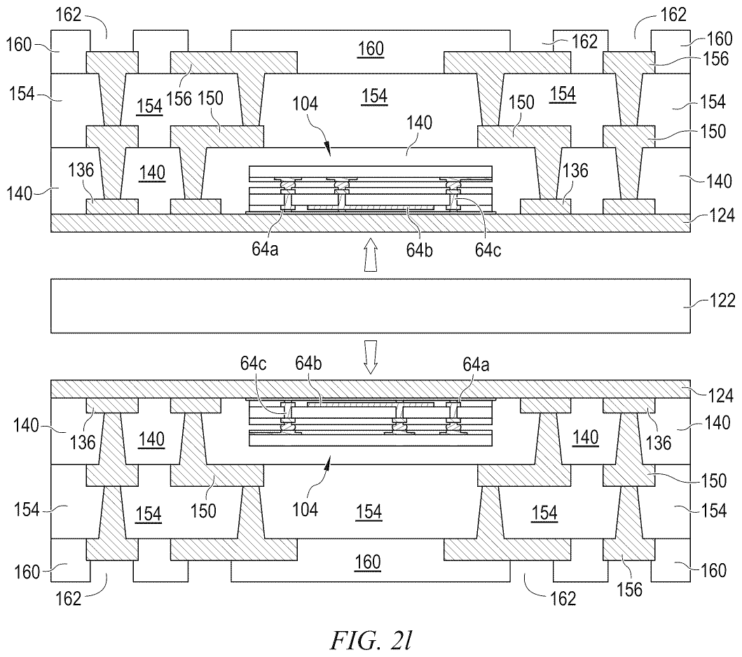

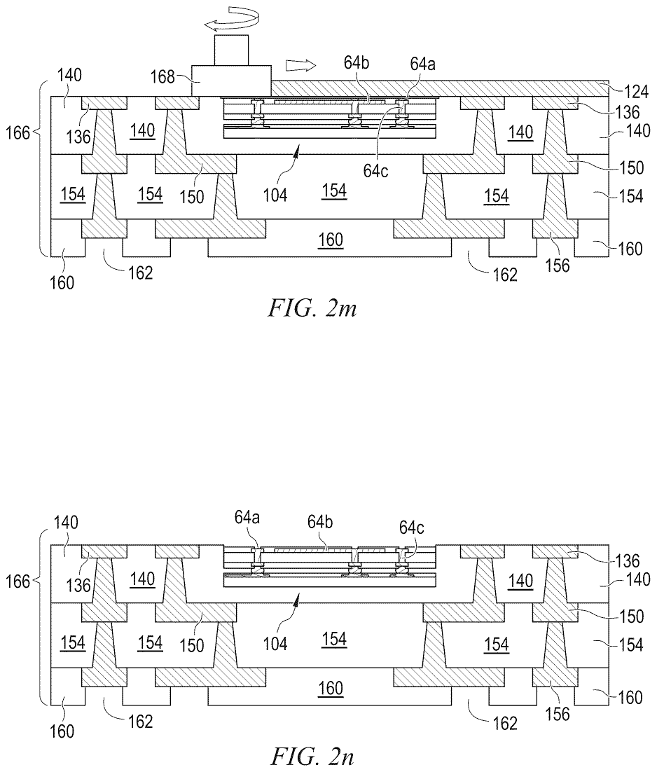

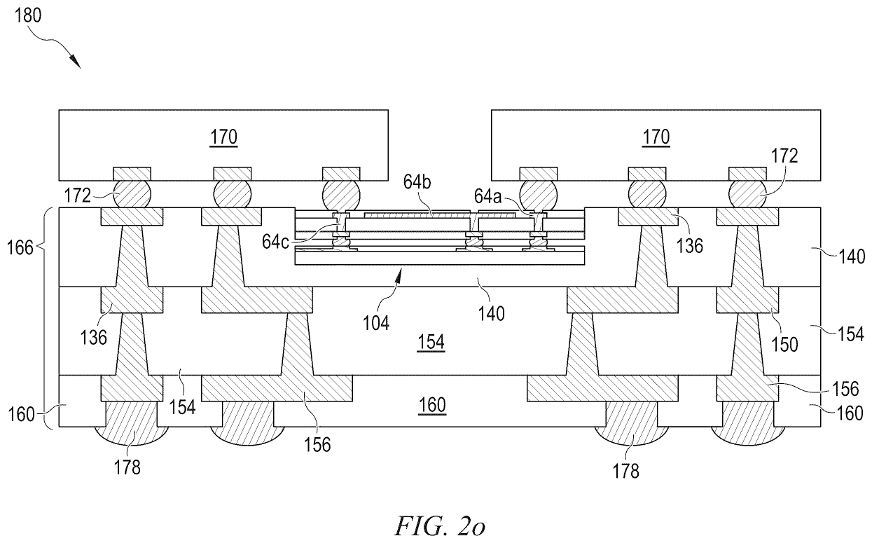

FIGS. 2a-2o illustrate a process of forming a chiplet or other type of semiconductor package with bridge module 104. FIG. 2a shows a copper-clad laminate (CCL) 120 board. CCL 120 includes a core 122 formed of a laminate or other type of printed circuit board (PCB) or substrate material with two opposing surfaces that are completely covered in copper or other conductive layers 124. Any type of temporary carrier or substrate can be used in other embodiments instead of CCL 120.

While only a single unit is shown being formed, CCL 120 is typically provided large enough for hundreds of units to be formed together before singulating near the end of the process. Each of the following manufacturing steps that occurs on both sides of CCL 120 can either be performed on both sides in unison or can be formed on one side at a time with the CCL being flipped from side-to-side between each step. In another embodiment, the illustrated steps are all performed on one side of CCL 120 before flipping the CCL and re-performing each step on the opposite surface of the CCL. There are also some embodiments, especially where another type of carrier is used, where processing only ever occurs on a single side of the carrier.

In FIG. 2b, a photoresist layer 130 is formed over conductive layer 124. Openings 132 are formed through photoresist layers 130. Openings 132 expose conductive layers 124 for deposition of conductive material to form contact pads 136 directly on the conductive layers in FIG. 2c. Photoresist layer 130 is removed in FIG. 2d leaving contact pads 136 extending above conductive layers 124. In some embodiments, contact pads 136 are part of a conductive layer that also includes conductive traces for fan-in or fan-out. The term conductive layer may refer to contact pads 136 as a group with or without conductive traces.

FIG. 2d shows a bridge module 104 being disposed onto CCL 120 after removing photoresist layer 130. Bridge module 104 is disposed with electrical component 80 oriented away from CCL 120. An adhesive layer 117 is optionally added onto bridge die 54 or CCL 120 prior to mounting. Adhesive layer 117 can be a double-sided adhesive tape applied prior to singulating when forming bridge modules 104 above. Alternatively, adhesive layer 117 can be a liquid adhesive applied to either bridge die 54 or CCL 120 immediately prior to mounting bridge modules 104. Adhesive layer 117 extends from insulating layer 66 to conductive layer 124 to attach bridge module 104 to CCL 120. In FIG. 2e, bridge modules 104 are disposed on both opposing surfaces of CCL 120 with electrical components 80 oriented away in each case. Bridge modules 104 are disposed on conductive layers 124 between contact pads 136 using a pick and place operation.

In FIG. 2f, an insulating layer 140 is formed covering each side of CCL 120 over bridge module 104. Insulating layers 140 contain one or more layers of silicon dioxide (SiO2), silicon nitride (Si3N4), silicon oxynitride (SiON), tantalum pentoxide (Ta2O5), aluminum oxide (Al2O3), solder resist, polyimide (PI), photosensitive polyimide (PSPI) benzocyclobutene (BCB), polybenzoxazoles (PBO), and other material having similar insulating and structural properties. Insulating layer 140 can be formed using PVD, CVD, printing, lamination, spin coating, spray coating, sintering, or thermal oxidation. Any insulating, passivation, solder resist, or dielectric layer mentioned above or below can be formed using any of the materials or methods described for insulating layer 140. Insulating layers 140 are sheets of prepreg applied using lamination in one embodiment.

In FIG. 2g, openings 142 are formed through insulating layers 140 to expose contact pads 136 for subsequent electrical interconnect. Openings 142 are formed by laser-direct ablation, by mechanical etching, by chemical etching, or by another suitable method. Openings 142 are optionally formed down to contact pads of electrical component 80 in other embodiments.

A conductive layer 150 is formed over insulating layer 140 in FIG. 2h. Conductive layer 150 is formed using any of the materials and methods described above for conductive layers and 114. Conductive layer 150 fills openings 142 to provide conductive vias for vertical interconnect through insulating layer 140. Conductive layer 150 also optionally includes conductive traces to fan-in or fan-out interconnect across the surface of insulating layer 140. Other portions of conductive layer 150 only provide vertical interconnect and a contact pad for subsequent electrical interconnect.

In FIG. 2i, an additional insulating layer 154 and conductive layer 156 are formed over insulating layer 140 and conductive layer 150. Insulating layer 154 is formed of similar materials and methods as described above for insulating layer 140. Conductive layer 156 is formed of similar materials and methods as described above for conductive layer 150. Conductive layer 156 is patterned to include conductive vias through insulating layer 154 to physically and electrically contact conductive layer 150, and conductive traces to fan-in or fan-out electrical connections if desired. While two redistribution layers (RDL) are shown formed over CCL 120, any number of insulating and conductive layers can be interleaved over the CCL to implement the desired signal routing.

A solder resist layer 160 is formed over insulating layer 154 and conductive layer 156 in FIG. 2j. Solder resist layer 160 can be formed using any of the materials and methods discussed above for insulating layers generally. In FIG. 2k, solder resist layer 160 has openings 162 formed therethrough to expose contact pads of conductive layer 156. Openings 162 can be formed by laser ablation, chemical etching, photolithography, or another suitable method.

In FIG. 2l, CCL 120 is deconstructed by separating conductive layers 124 from core 122. Conductive layer 124 can be separated from core 122 by mechanical peeling, thermal release, or another suitable means. Each side, both the top and the bottom, of CCL 120 becomes a separate embedded trace substrate (ETS) 166. From here on, each side of CCL 120, as constructed above, is separately processed as its own panel or ETS 166. When other types of carriers are used, ETS 166 may be peeled from the carrier without needing to remove conductive layer 124.

In FIG. 2m, ETS 166 is oriented with conductive layer 124 exposed for removal. Removal of conductive layer 124 is illustrated as being done by a grinder 168, but chemical etching, chemical-mechanical planarization (CMP), laser ablation, or another suitable method is used in other embodiments. If necessary, adhesive 117 is removed as a separate step in FIG. 2n. Removing conductive layer 124 and adhesive 117 exposes contact pads 136 and contact pads 64a of bridge die 54.

In FIG. 2n, ETS 166 is completed and ready to be used to form a semiconductor package or chiplet. ETS 166 in FIG. 2n can be singulated at this stage, or later after being used to form semiconductor packages. ETS 166 can be used as a substrate to form any type of semiconductor package. In some embodiments, ETS 166 with bridge module 104 is the final product sold by a substrate manufacturer, and a semiconductor package or device manufacturer forms semiconductor packages using the ETS.

As one basic example of forming a chiplet with ETS 166, a pair of semiconductor die 170 is mounted onto contact pads 136 and contact pads 64a of bridge module 104 in FIG. 2o. Semiconductor die 170 are formed from a semiconductor wafer similar to wafer 50. Semiconductor die 170 are used for their active functionality implemented using transistors, diodes, and other circuit elements formed in or on the semiconductor die. Solder bumps 172 are reflowed between semiconductor die 170 and contact pads 136 and 64a to mechanically and electrically connect the semiconductor die to the contact pads. An underfill is used between semiconductor die 170 and the underlying substrate in some embodiments.

An encapsulant may also be deposited to cover semiconductor die 170, or with a top surface coplanar to the semiconductor die. The encapsulant material can be deposited using a paste printing, compressive molding, transfer molding, liquid encapsulant molding, vacuum lamination, spin coating, or another suitable applicator. The encapsulant can be liquid or granular polymer composite material, such as epoxy resin, epoxy acrylate, or polymer, with or without an added filler.

Each semiconductor die 170 is mounted over one of two opposing sides of bridge module 104 that have contact pads 64a formed thereon, and the semiconductor die are connected to each other through bridge die 54. Semiconductor die 170 may each be disposed directly over one side of bridge module 104, or slightly outside of the footprint of the bridge die where a short interconnect is still possible. Bridge module 104 also provides electrical interconnect for both semiconductor die 170 to electrical component 80 through vias 64c. The more advanced integration provided by mounting bridge die 54 as part of a bridge module 104 with electrical component 104 allows smaller and more advanced chiplet designs.

An electrically conductive bump material is deposited over conductive layer 156 in openings 162 using an evaporation, electrolytic plating, electroless plating, ball drop, or screen printing process. The bump material can be Al, Sn, Ni, Au, Ag, lead (Pb), bismuth (Bi), Cu, solder, and combinations thereof, with an optional flux solution. For example, the bump material can be eutectic Sn/Pb, high-lead solder, or lead-free solder. The bump material is bonded to conductive layer 156 using a suitable attachment or bonding process. In one embodiment, the bump material is reflowed by heating the material above its melting point to form balls or bumps 178. In one embodiment, bump 178 is formed over an under-bump metallization (UBM) having a wetting layer, a barrier layer, and an adhesion layer.

Bump 178 can also be compression bonded or thermocompression bonded to conductive layer 156. Bump 178 represents one type of interconnect structure that can be formed over conductive layer 156. The interconnect structure can also use bond wires, conductive paste, stud bump, micro bump, or other electrical interconnect. In some embodiments, bumps 178 are formed by the ETS 166 manufacturer prior to beginning to form a semiconductor package or chiplet using the ETS. Bumps 172 on semiconductor die 170 can be formed in the same way and using the same materials as bumps 178.

FIG. 2o shows a completed chiplet 180 ready to be integrated into a larger electronic device or semiconductor package. In most embodiments, a large ETS 166 is used to form a plurality of chiplets 180 at once. After completion of chiplets 180 or other semiconductor package on ETS 166 in FIG. 2o, the ETS and packages are singulated from each other by cutting through the ETS and any encapsulant or underfill, if used, to result in a plurality of the structures shown in FIG. 2o separated from each other. The added integration of combining bridge die 54 with electronic device 80 into a bridge module 104 reduces manufacturing costs and device size.

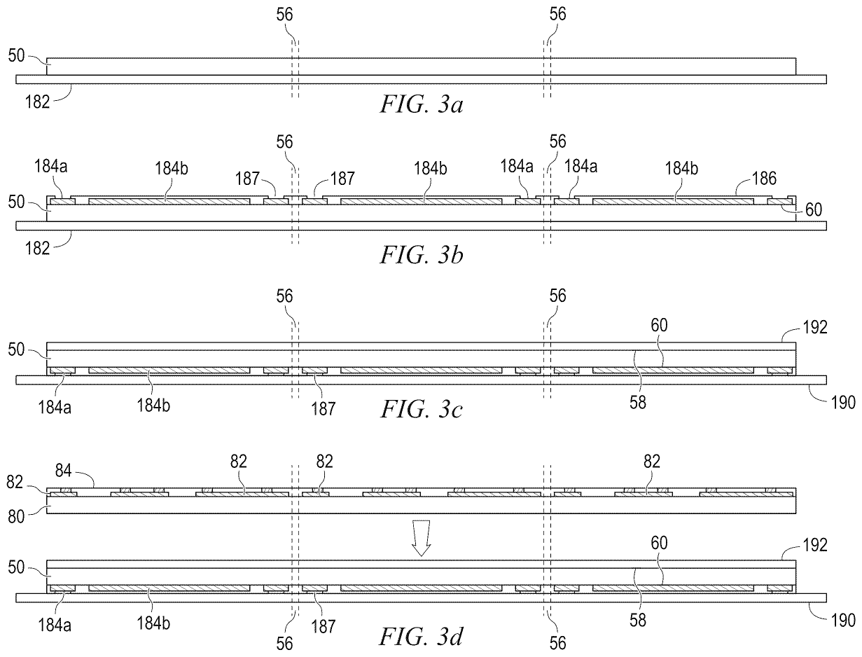

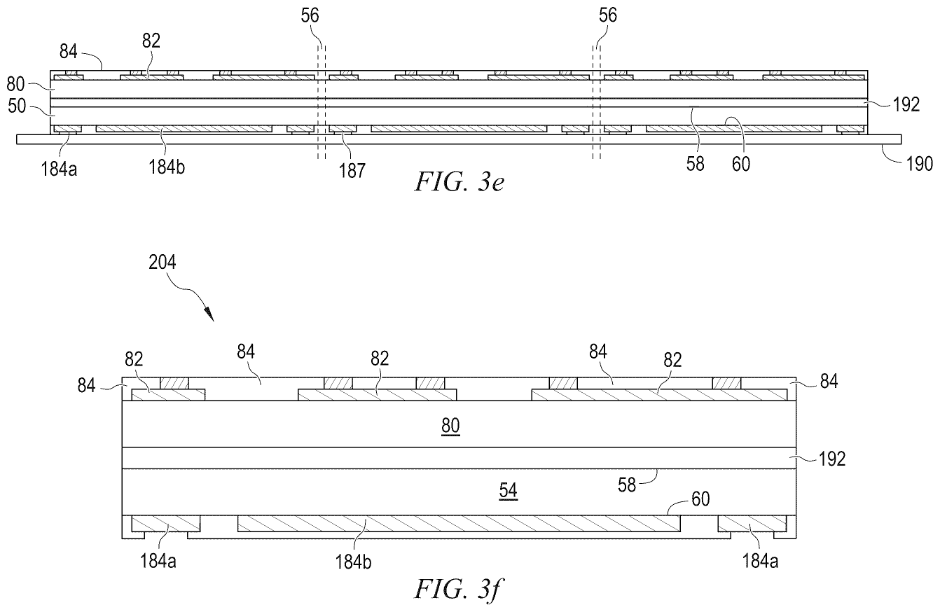

FIGS. 3a-3f illustrate another embodiment of forming a bridge module. Wafer 50 is disposed on carrier 182 in FIG. 3a. In FIG. 3b, a conductive layer 184 with fine-pitched interconnects is formed as described above for conductive layer 64, including conductive traces 184b that connect from contact pads 184a on one side of each bridge die 54 to contact pads on the opposite side. Solder resist layer 186 is formed as described above, with openings 187 to expose contact pads 184a.

In FIG. 3c, wafer 50 is flipped onto a new carrier 190 so that surface 58 is oriented up. Wafer 50 could also be placed back onto the same carrier upside down. An adhesive layer 192 is disposed or deposited onto surface 58. Adhesive layer 192 can be a sheet of adhesive, a liquid adhesive, a double-sided tape, or any other suitable type of adhesive. In FIG. 3d, a panel or wafer of electronic components 80 is disposed over wafer 50 with conductive layer 82 oriented away from the bottom wafer. The back surfaces of electronic components 80 and wafer 50 are attached to each other by adhesive 192 when the electronic component is set down in FIG. 3e. Bridge die 54, electronic component 80, or both can be attached at the die level instead of as a wafer.

The combination of wafer 50 and electronic components 80 is singulated using a saw blade or laser cutting tool to complete a bridge module 204 in FIG. 3f. Bridge module 204 includes a bridge die 54 connectable from one side of the bridge module and an electronic component 80 connectable from the opposite side.

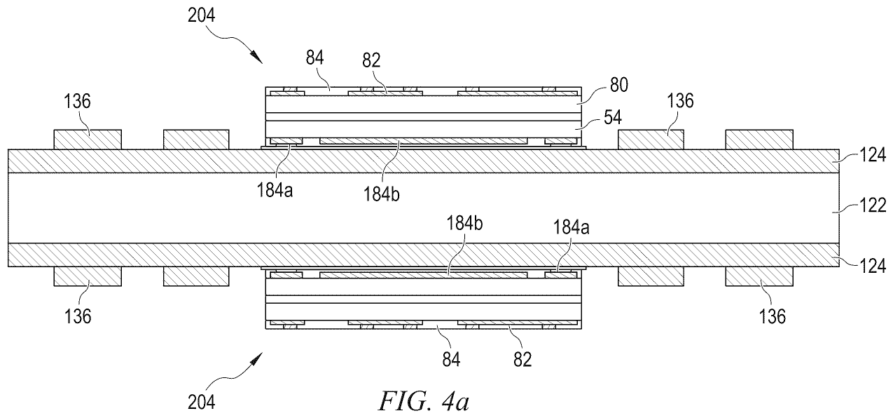

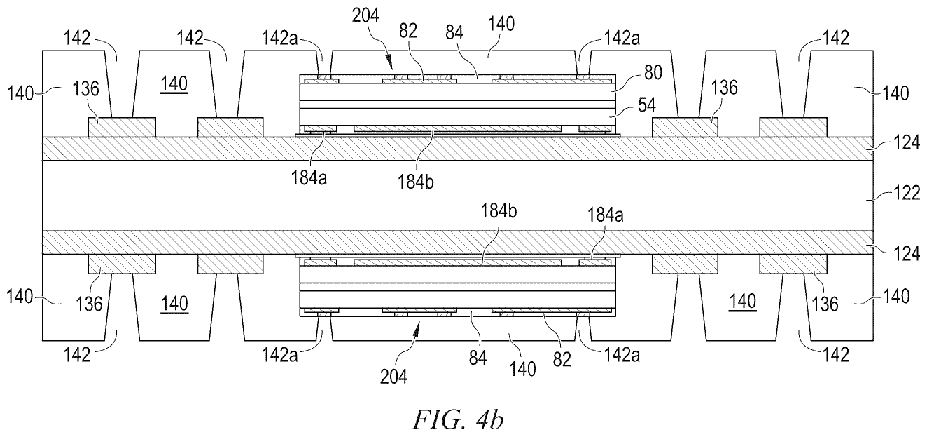

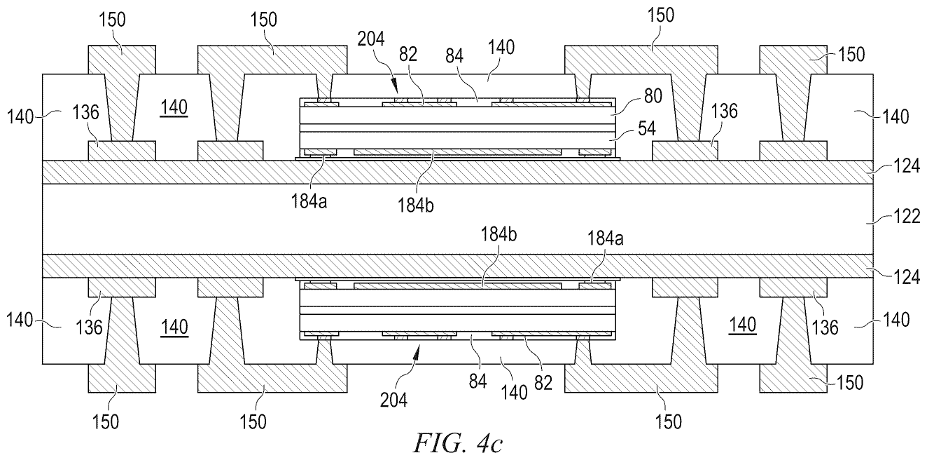

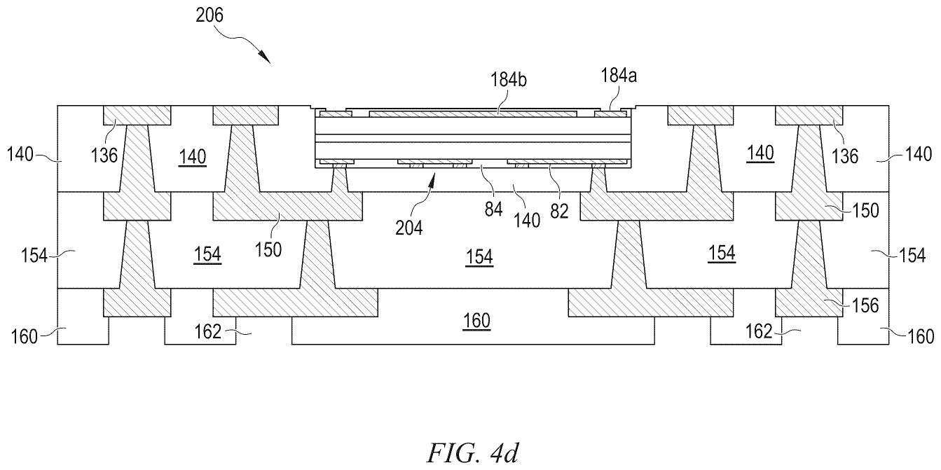

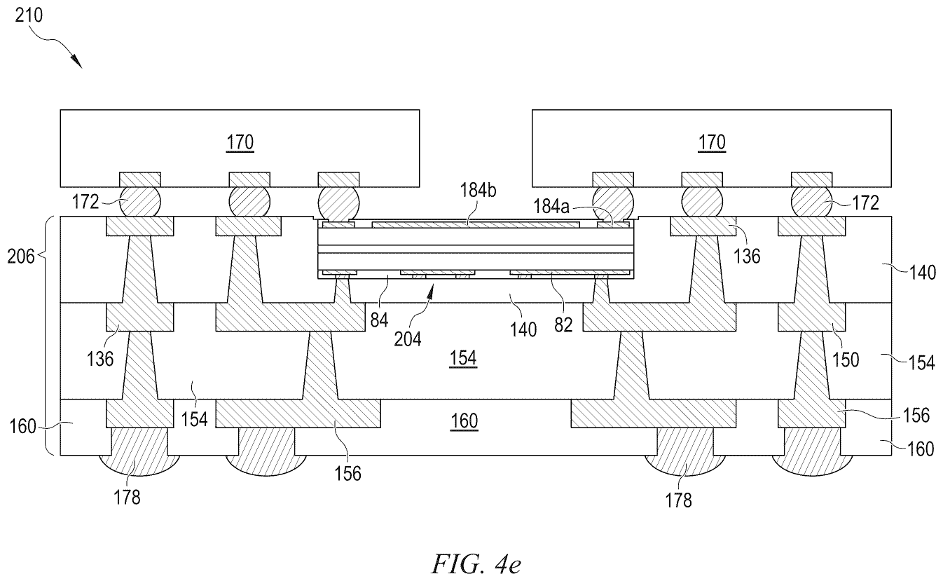

FIGS. 4a-4e illustrate the formation of a chiplet or semiconductor package using bridge module 204. The process proceeds very similarly to the process shown in FIGS. 2a-2o for making chiplet 180 with bridge module 104. FIG. 4a continues from FIG. 2c, with bridge modules 204 being disposed on CCL 120 instead of bridge modules 104. Bridge modules 204 are disposed with bridge die 54 oriented toward CCL 120 and electronic components 80 oriented away from the CCL.

When vias 142 are formed in FIG. 4b, as in FIG. 2g above, additional vias 142a are formed over bridge module 204 to expose contact pads of conductive layer 82. When conductive layer 150 is formed in FIG. 4c, as in FIG. 2h above, conductive layer 150 has portions that extend through openings 142a to conductive layer 82, thereby electrically connecting to electronic component 80.

FIG. 4d shows an ETS 206 completed as described above in FIGS. 2l-2n. ETS 206 can be an end product for a substrate manufacturing company, or an intermediate product for a chiplet manufacturer that also manufactures the ETS. Semiconductor die 170 are added in FIG. 4e to complete a chiplet 210. Chiplet 210 has a bridge module 204 that combines a bridge die 54 with another electronic component 80. Semiconductor die 170 each connects directly to bridge die 54, and to the other semiconductor die 170 through the bridge die. Semiconductor die 170 connect to electrical component 80 through conductive layer 150 of ETS 206. The added integration of combining bridge die 54 with electronic device 80 into a bridge module 204 reduces manufacturing costs and device size.

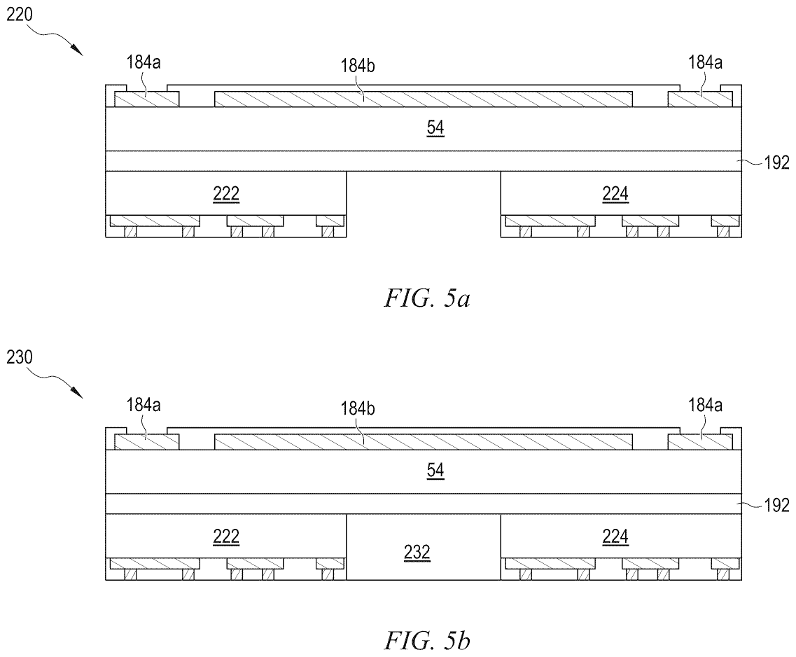

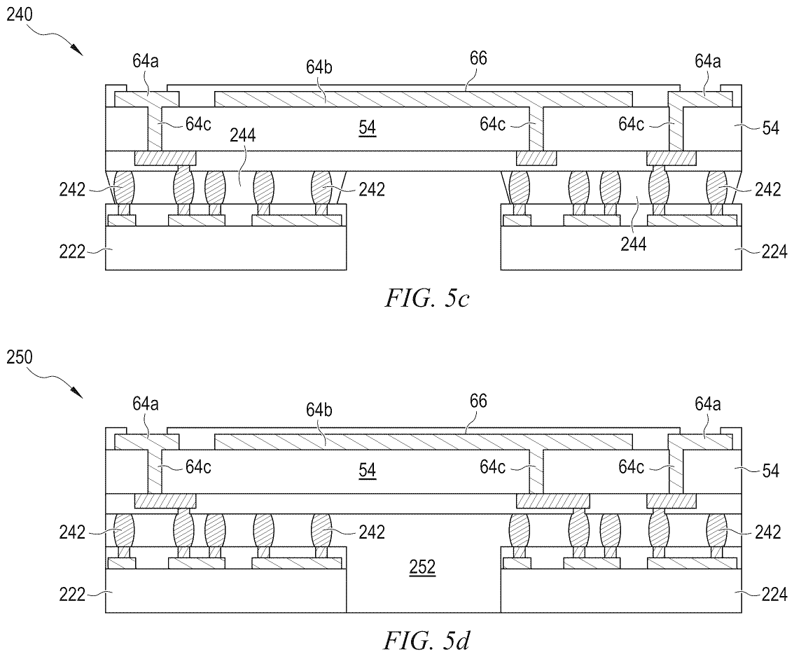

FIGS. 5a-5d illustrate additional bridge module embodiments with multiple electrical components mounted onto bridge die 54. In FIG. 5a, bridge module 220 has two electrical components 222 and 224 mounted onto the back surface of bridge die 54 in a similar manner to electrical component 80 being mounted in FIG. 3d. The two components can be split such that component 222 is for use by a first semiconductor die 170 while the other component 224 is used by the second semiconductor die. Alternatively, one component 222 could be a die with active devices while component 224 is a die with passive components.

Bridge module 220 can be used as-is instead of bridge module 204 in FIGS. 4a-4e. Alternatively, a mold underfill or encapsulant 232 can be used to fill in the gap between electrical components 222 and 224 as shown with bridge module 230 in FIG. 5b. Encapsulant 232 is deposited using a paste printing, compression molding, transfer molding, liquid encapsulant molding, vacuum lamination, spin coating, or other suitable applicator. Encapsulant 232 can be liquid or granular polymer composite material, such as epoxy resin, epoxy acrylate, or another suitable polymer, with or without a filler. Encapsulant 232 is non-conductive, provides structural support, and environmentally protects the semiconductor device from external elements and contaminants. Either bridge module 220 or 230 can be used in the embodiment of FIGS. 4a-4e, with electrical components 222 and 224 connected to semiconductor die 170 by conductive layer 150.

FIG. 5c illustrates an embodiment as bridge module 240 with solder bumps 242 used to electrically connect electrical components 222 and 224 to bridge die 54. Solder bumps 242 are formed as described above for other solder bumps. An underfill 244 physically supports the electrical and physical connection provided by solder bumps 242. Electrical components 222 and 224 are connected through bridge die 54 by conductive vias of conductive layer 64. FIG. 5d shows an embodiment as bridge module 250 with encapsulant 252 used instead of or in addition to underfill 244. Encapsulant 252 is deposited as described above for encapsulant 232. Either bridge modules 240 or 250 can be used in the embodiment of FIGS. 2a-2o, with semiconductor die 170 connected to electrical components 222 and 224 through conductive layer 64. Any type and number of electrical components can be mounted onto a bridge die 54.

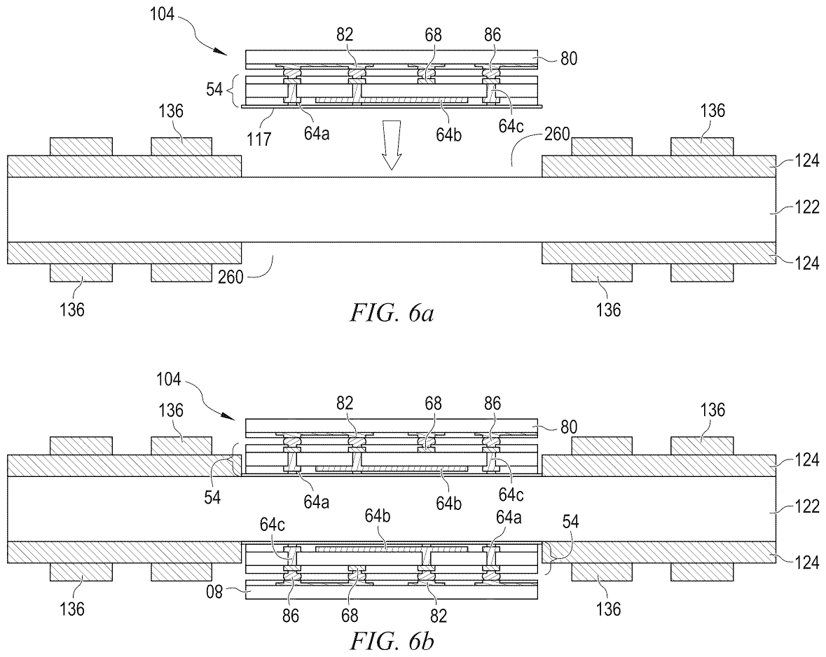

FIGS. 6a and 6b illustrate an embodiment where the bridge module is disposed on CCL 120 in an opening 260 of conductive layer 124. FIG. 6a illustrates CCL 120 with opening 260 formed. Bridge modules 104 are disposed in openings 260 in FIG. 6b, directly on core 122. Any of the above-disclosed bridge modules could be used with opening 260. A chiplet is then completed as disclosed above in FIGS. 2f-2o, but with bridge module 104 setting lower, which reduces overall device thickness of the ETS and chiplet being formed.

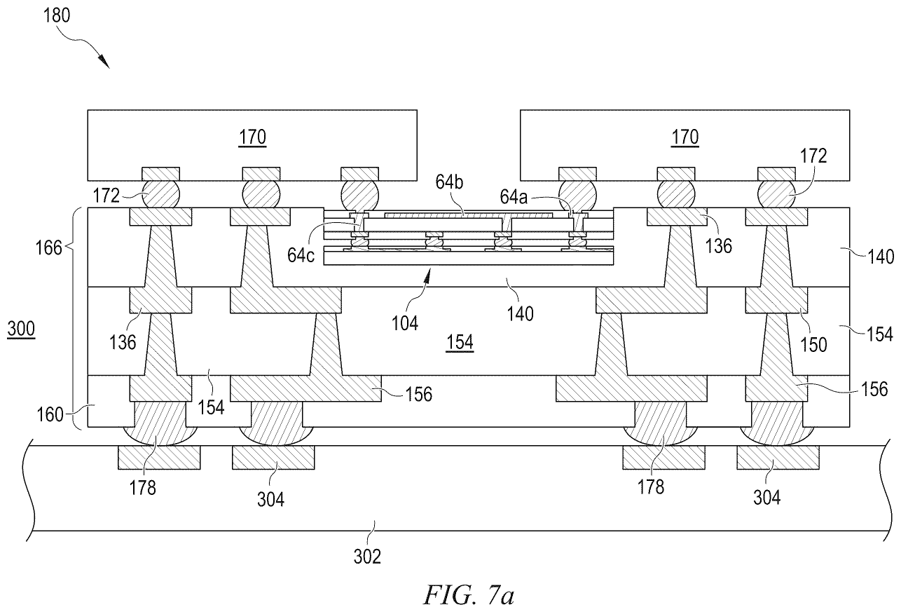

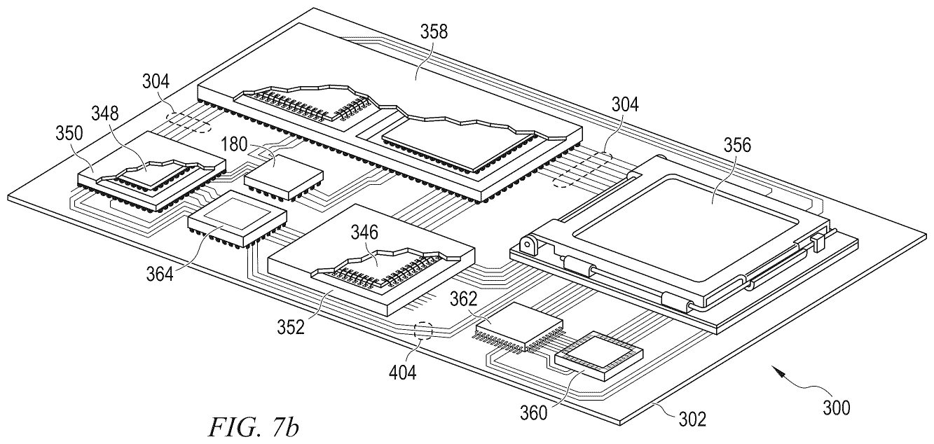

FIGS. 7a and 7b illustrate integrating the above-described semiconductor packages, e.g., chiplet 180, into a larger electronic device 300. FIG. 7a illustrates a partial cross-section of chiplet 180 mounted onto a printed circuit board (PCB) or other substrate 302 as part of electronic device 300. Solder bumps 178 are reflowed onto conductive layer 304 of PCB 302 to physically attach and electrically connect chiplet to the PCB. In other embodiments, thermocompression or another suitable attachment and connection methods are used. In some embodiments, an adhesive or underfill layer is used between chiplet 180 and PCB 302. Semiconductor die 170 are electrically coupled to conductive layer 304 through ETS 166. ETS 166 also includes bridge module 104 that electrically couples the two semiconductor die 170 to each other. In addition, bridge module 104 includes additional active and/or passive electrical components 80 to supplement the functionality of semiconductor die 170. Integrating bridge die 54 with electrical component 80, or other additional electrical components, increases the level of integration, reducing device size, manufacturing complexity, and cost.

FIG. 7b illustrates electronic device 300 having a chip carrier substrate or PCB 302 with a plurality of semiconductor packages disposed on a surface of PCB 302, including chiplet 180. Electronic device 300 can have one type of semiconductor package, or multiple types of semiconductor packages, depending on the application. In other embodiments, chiplet 180 is incorporated as only one part of another larger semiconductor package, e.g., a system-in-package, before being incorporated into a larger electronic device 300.

Electronic device 300 can be a stand-alone system that uses the semiconductor packages to perform one or more electrical functions. Alternatively, electronic device 300 can be a subcomponent of a larger system. For example, electronic device 300 can be part of a tablet, cellular phone, digital camera, communication system, or other electronic device. Alternatively, electronic device 300 can be a graphics card, network interface card, or other signal processing card that can be inserted into a computer. The semiconductor package can include microprocessors, memories, ASICs, logic circuits, analog circuits, RF circuits, discrete devices, or other semiconductor die or electrical components. Miniaturization and weight reduction are essential for the products to be accepted by the market. The distance between semiconductor devices may be decreased to achieve higher density. PCB 302 may have a more irregular shape to fit conveniently into more ergonomic and smaller device shells.

In FIG. 7b, PCB 302 provides a general substrate for structural support and electrical interconnect of the semiconductor packages disposed on the PCB. Conductive signal traces 304 are formed over a surface or within layers of PCB 302 using evaporation, electrolytic plating, electroless plating, screen printing, or other suitable metal deposition process. Signal traces 304 provide for electrical communication between each of the semiconductor packages, mounted components, and other external system components. Traces 304 also provide power and ground connections to each of the semiconductor packages.

In some embodiments, a semiconductor device has two packaging levels. First level packaging is a technique for mechanically and electrically attaching the semiconductor die to an intermediate substrate. Second level packaging involves mechanically and electrically attaching the intermediate substrate to the PCB. In other embodiments, a semiconductor device may only have the first level packaging where the die is mechanically and electrically disposed directly on the PCB.

For the purpose of illustration, several types of first level packaging, including bond wire package 346 and flipchip 348, are shown on PCB 302. Additionally, several types of second level packaging, including ball grid array (BGA) 350, bump chip carrier (BCC) 352, land grid array (LGA) 356, multi-chip module (MCM) or SIP module 358, quad flat non-leaded package (QFN) 360, quad flat package 362, and embedded wafer level ball grid array (eWLB) 364 are shown disposed on PCB 302. In one embodiment, eWLB 364 is a fan-out wafer level package (Fo-WLP) or a fan-in wafer level package (Fi-WLP).

Depending upon the system requirements, any combination of semiconductor packages, configured with any combination of first and second level packaging styles, as well as other electrical components, can be connected to PCB 302. In some embodiments, electronic device 300 includes a single attached semiconductor package, while other embodiments call for multiple interconnected packages. By combining one or more semiconductor packages over a single substrate, manufacturers can incorporate pre-made components into electronic devices and systems. Because the semiconductor packages include sophisticated functionality, electronic devices can be manufactured using less expensive components and a streamlined manufacturing process. The resulting devices are less likely to fail and are less expensive to manufacture, resulting in a lower cost for consumers.

While one or more embodiments of the present invention have been illustrated in detail, the skilled artisan will appreciate that modifications and adaptations to those embodiments may be made without departing from the scope of the present invention as set forth in the following claims.

What is claimed:

1. A method of making a semiconductor device, comprising:
providing a bridge die comprising a contact pad;
mounting an electrical component to the bridge die to form a bridge module;
disposing the bridge module over a carrier;
forming a first conductive layer on the carrier;
forming a first insulating layer over the first conductive layer and bridge module;
forming an opening through the first insulating layer to expose the first conductive layer;
forming a second conductive layer over the first insulating layer;
removing the carrier; and
mounting a first semiconductor die electrically coupled to the electrical component and bridge die.

2. The method of claim 1, further including forming a second insulating layer over the first insulating layer and second conductive layer.

3. The method of claim 1, further including mounting a second semiconductor die electrically coupled to the first semiconductor die through the bridge die.

4. The method of claim 1, wherein the carrier is a copper-clad laminate (CCL).

5. The method of claim 4, wherein removing the carrier includes:
separating a core of the CCL from a copper layer of the CCL; and
removing the copper layer from the first insulating layer, first conductive layer, and bridge module after separating the core from the copper layer.

6. The method of claim 5, further including:
forming an opening in the copper layer; and
disposing the bridge module directly on the core in the opening.

7. A method of making a semiconductor device, comprising:
providing a bridge die;
mounting an electrical component to the bridge die to form a bridge module;
disposing the bridge module over a carrier;
forming a first conductive layer on the carrier;
forming a first insulating layer over the first conductive layer and bridge module;
forming a second conductive layer over the first insulating layer;
removing the carrier; and
mounting a first semiconductor die electrically coupled to the electrical component and bridge die.

8. The method of claim 7, further including forming a second insulating layer over the first insulating layer and second conductive layer.

9. The method of claim 8, further including forming a third conductive layer over the second insulating layer, wherein the third conductive layer includes a conductive via extending through the second insulating layer to contact the second conductive layer.

10. The method of claim 7, wherein the carrier is a copper-clad laminate (CCL).

11. The method of claim 10, wherein removing the carrier includes:
separating a core of the CCL from a copper layer of the CCL; and
removing the copper layer from the first insulating layer, first conductive layer, and bridge module after separating the core from the copper layer.

12. The method of claim 7, further including mounting a second semiconductor die electrically coupled to the first semiconductor die through the bridge die.

13. The method of claim 7, further including mounting a second electrical component to the bridge die as part of the bridge module.

14. A method of making a semiconductor device, comprising:
providing a bridge die;
mounting an electrical component to the bridge die to form a bridge module;
disposing the bridge module over a carrier;
forming a first insulating layer over the first conductive layer and bridge module;
removing the carrier; and
mounting a first semiconductor die to the bridge die.

15. The method of claim 14, further including forming a conductive layer over the first insulating layer including a conductive via of the conductive layer extending through the first insulating layer.

16. The method of claim 15, further including forming a second insulating layer over the first insulating layer and conductive layer.

17. The method of claim 14, wherein the carrier is a copper-clad laminate (CCL).

18. The method of claim 17, wherein removing the carrier includes:
separating a core of the CCL from a copper layer of the CCL; and
removing the copper layer from the first insulating layer and bridge module after separating the core from the copper layer.

19. The method of claim 14, further including mounting a second semiconductor die to the bridge die.

20. A semiconductor device, comprising:
a bridge module comprising a bridge die and a first electrical component mounted to the bridge die;
a first conductive layer formed adjacent to the bridge module; and
a first semiconductor die disposed over the bridge die and electrically coupled to the first conductive layer and bridge die, wherein the first semiconductor die is electrically coupled to the first electrical component through the first conductive layer.

21. The semiconductor device of claim 20, further including an insulating layer formed over the bridge die and first conductive layer.

22. The semiconductor device of claim 20, further including a second conductive layer formed over the insulating layer, wherein the second conductive layer includes a conductive via in contact with the first conductive layer.

23. The semiconductor device of claim 20, wherein the bridge module includes a second electrical component mounted to the bridge die.

24. The semiconductor device of claim 23, wherein the first electrical component includes active components and the second electrical component includes passive components.

25. The semiconductor device of claim 20, further including a second semiconductor die, wherein the second semiconductor die is coupled to the first semiconductor die through the bridge die.
